(19) United States
(12) Patent Application Publication
(10) Pub. No.: US 2012/0118355 A1
(43) Pub. Date: May 17, 2012

(54) FLEXIBLE SOLAR SHELL AND SUPPORT STRUCTURE FOR USE WITH ROOFTOPS

(75) Inventor: Donald E. Rudolfs, San Jose, CA (US)

(73) Assignee: SoloPower, Inc., San Jose, CA (US)

(21) Appl. No.: 12/945,759

(22) Filed: Nov. 12, 2010

(51) Int. Cl. H01L 31/048; H01L 31/18; B21D 53/02

(52) U.S. Cl. 136/251; 29/890.033

(57) ABSTRACT

A system and method for mounting flexible sheets containing solar cells adjacent the rooftop of a building. A plurality of support members are mounted to the building so that holes are not formed in the rooftop to mount the support members. Wires are then extended between the support members and the flexible sheets containing the solar cells are then mounted to the wires.

### BACKGROUND OF THE INVENTION

1. Field of the Invention

The present inventions generally relate to apparatus and methods of solar module design and fabrication and, more particularly, to rooftop photovoltaic systems and methods.

2. Description of the Related Art

Solar cells are photovoltaic (PV) devices that convert sunlight directly into electrical energy. Solar cells can be based on crystalline silicon or thin films of various semiconductor materials, usually deposited on low-cost substrates, such as glass, plastic, or stainless steel.

Thin film-based photovoltaic cells, such as amorphous silicon, cadmium telluride, and copper indium diselenide, offer improved cost by employing deposition techniques widely used in the thin film industry. Group IBIIIAVIA compound photovoltaic cells, including copper indium gallium diselenide (CIGS) based solar cells, have demonstrated the greatest potential for high performance, high efficiency, and low cost thin film PV products.

A structure for a conventional Group IBIIIAVIA compound photovoltaic cell 10 is shown in FIG. 1. The photovoltaic cell 10 generally includes a base 11 having a substrate 12 and a conductive layer 13 formed on the substrate. The substrate 12 can be a sheet of glass, a sheet of metal, an insulating foil or web, or a conductive foil or web. An absorber thin film 14, which includes a material in the family of Cu(In,Ga)(S,Se)₂, is formed on the conductive layer 13. Although there are other methods, Cu(In,Ga)(S,Se)₂₋ type compound thin films are typically formed by a two-stage process where the components (components including Cu, In, Ga, Se and S) of the Cu(In,Ga)(S,Se)₂ material are first deposited onto the substrate or the contact layer formed on the substrate as an absorber precursor, and then reacted with S and/or Se in a high temperature annealing process to form the absorber film 14.

The conductive layer 13 can be a Mo layer and functions as an ohmic contact to the photovoltaic cell. After the absorber film 14 is formed, a transparent layer 15, for example, a CdS, ZnO or CdS/ZnO film stack, is formed on the absorber film. Light 16 enters the photovoltaic cell 10 through the transparent layer 15. Metallic grids (not shown) are formed over the transparent layer 15 to reduce the effective series resistance of the device. The preferred electrical type of the absorber film 14 is p-type, and the preferred electrical type of the transparent layer 15 is n-type. However, an n-type absorber and a p-type window layer can also be formed. The device structure shown FIG. 1 is called a substrate-type structure. A so called superstrate-type structure can also be formed by depositing a transparent conductive layer on a transparent superstrate such as glass or transparent polymeric foil, and then forming the Cu(In,Ga)(S,Se)₂ absorber film, and finally forming an ohmic contact to the device by a conductive layer. In the superstrate structure light enters the device from the transparent superstrate side.

In standard CIGS as well as Si and amorphous Si module technologies, the solar cells are manufactured on conductive substrates, such as aluminum or stainless steel foils. In such solar cells, the transparent layer, e.g., the transparent layer 15 in FIG. 1, and the conductive substrate, e.g., the substrate 12 in FIG. 1, form the opposite poles of the solar cell. Multiple solar cells can be electrically interconnected by stringing or shingling methods that establish electrical connection between the opposite poles of the solar cells. Such interconnected solar cells are then packaged in protective packaging materials to form solar modules or panels. Many modules can also be combined to form large solar panels. Each module typically includes multiple solar cells which are electrically connected to one another using above mentioned stringing or shingling interconnection methods. The solar modules are constructed using various packaging materials to mechanically support and protect the solar cells in them against physical and chemical damage, especially against moisture.

In general, solar panels are placed on rooftops, often on roof shingles or other varieties of rooftop structures, to directly expose them to unobstructed sunlight. The modules are either directly secured onto the rooftops or onto a rack and then securing the rack onto the rooftops. However considering most solar panels are installed on rooftops in large numbers, installers often attach the panels to underlying roof support structures using various attachment means such as nails or screws inserted through the shingles and the layers of roof seals or protective roof shields. Such installation methods make the rooftop less weather resistant. This installation approach also further complicates replacements and maintenance of the solar panels that are, in some cases, permanently anchored to the roof support structures. Since the solar panels are permanently attached to the rooftop, any maintenance work will result in further damage the rooftop.

From the foregoing, there is a need in the solar cell industry, especially in thin film photovoltaics, for better rooftop installation techniques that result in easy to maintain solar panels so that replacements and repairs can be performed in short time and reduced cost. Such techniques should not require alterations in the existing rooftop structure.

### SUMMARY OF THE INVENTION

The aforementioned needs are satisfied by the present invention which, in one exemplary implementation, comprises a solar shell for a rooftop on a building having sidewalls, the solar shell including flexible solar cell modules. In this implementation the solar shell comprises at least one support structure formed on a rooftop including a roofing material, the at least one support structure including a first support member having a lower end and an upper end, wherein the upper end of the first support member is attached to a first location on the building; a second support member having a lower end and an upper end, wherein the lower end of the second support member is attached to a second location on the building; a first edge support wire segment extending between the upper ends of the first and second support members; and a second edge support wire segment, which is substantially parallel to the first wire, tensioned between the upper ends of the first and second support members. In this implementation, the solar shell also includes a flexible sheet-shaped solar module, including a plurality of solar cells, movably attached to the first and second edge support wire segments by fastening a first longitudinal peripheral edge of the flexible sheet-shaped solar module to the first wire segment and by fastening a second longitudinal peripheral edge of the flexible sheet-shaped solar module to the second wire segment and thereby orienting the flexible sheet-shaped solar module generally parallel to the rooftop.

In another exemplary implementation, the invention comprises a solar cell assembly for mounting on the rooftop of a building having horizontal surfaces adjacent the sidewall. In this implementation, the solar cell assembly comprises a plurality of support members attached to the building, wherein the plurality of support members includes at least one floating support member. In this implementation, the solar cell assembly further includes a plurality of wire segments that extend between the plurality of support members under tension wherein the plurality of wire segments are arranged into pairs of wire segments and wherein the plurality of wire segments exert a downward force on the at least one floating support member to retain the at least one floating support member in contact with the rooftop. In this implementation, the solar cell assembly includes a plurality of flexible sheets having solar cells formed thereon, wherein the plurality of flexible sheets are coupled between pairs of wire segments so that the tension on the wire segments suspend the plurality of flexible sheets over the rooftop.

In another exemplary implementation, the invention comprises a method of installing solar cells on the rooftop of a building. In this implementation, the method comprises installing a plurality of support members to the portions of the building so that the support members extend above the rooftop; extending a plurality of wire segments between the plurality of support members so that the one or more wires extend over the rooftop; and mounting flexible sheets containing solar cells to the plurality of wires so that the flexible sheets are positioned over the rooftop.

These and other aspects and advantages are described further herein.

### BRIEF DESCRIPTION OF THE DRAWINGS

FIG. 1 is a schematic view a solar cell;

FIG. 2A is a schematic view of an exemplary solar module used with the present invention;

FIG. 2B is a cross-sectional view of the solar module taken along the line 2B-2B;

FIG. 3 is a schematic illustration of a support system to install the solar module;

FIG. 4A is a schematic illustration of an embodiment of a rooftop solar module support system on a rooftop;

FIG. 4B is a schematic top view of the rooftop solar module shown in FIG. 4A;

FIG. 5A is a schematic illustration of another embodiment of a rooftop solar module support system on a rooftop;

FIG. 5B is a schematic detail view of a support member of the solar module support system shown in FIG. 5A;

FIG. 5C is a schematic detail view of another support member of the solar module support system shown in FIG. 5A;

FIGS. 6A-6B are schematic illustrations of alternative embodiments for the rooftop solar module support system;

FIGS. 7A-8B are schematic illustrations of various alternative embodiments of wiring networks for rooftop solar module support systems; and

FIGS. 9A-9F are schematic illustrations of various embodiments to attach solar modules to edge support wires of the solar module support systems.

### DETAILED DESCRIPTION OF THE PREFERRED EMBODIMENTS

The preferred embodiments described herein provide methods of installing flexible solar modules or panels including a plurality of solar cells over rooftops using a support structure, thereby forming a solar shell or soft solar cell frame on the rooftop. A flexible solar module is a laminated protective structure sealing a plurality of solar cells interconnected, preferably, in series. The solar cells are packed between a back protective sheet and a front protective sheet which is transparent. Light enters the solar modules from a transparent front side and is received by the solar cells. The solar module may preferably have a flat rectangular body with longitudinal edges and transversal edges which are shorter than the longitudinal edges.

The support structure of at least one embodiment of the present invention includes at least a first support member secured to a first location on the rooftop, a second support member secured to a second location on the rooftop and at least a pair of tensioned wires between the first support member and the second support member. The solar modules are attached to the support structure by the longitudinal edges. One of the longitudinal edges of the solar module is attached to one of the pair of wires and the other longitudinal edge is attached to the other wire, preferably movable, so that the panels can be moved to their optimum position. Once the installation is complete the solar module is suspended above the rooftop between the tensioned wires without touching the rooftop. In this suspended state, the flat body of the module may be generally parallel to the rooftop so that the back protective sheet of the solar module faces the rooftop. There may be a plurality of tensioned wires between the first and second support structures carrying a plurality of solar modules covering the rooftop. Each solar module may include an output terminal, such as a junction box, where the module outlet wires are connected. These outlet wires are in turn connected to a power circuitry to harvest the energy produced by the solar cells in the modules.

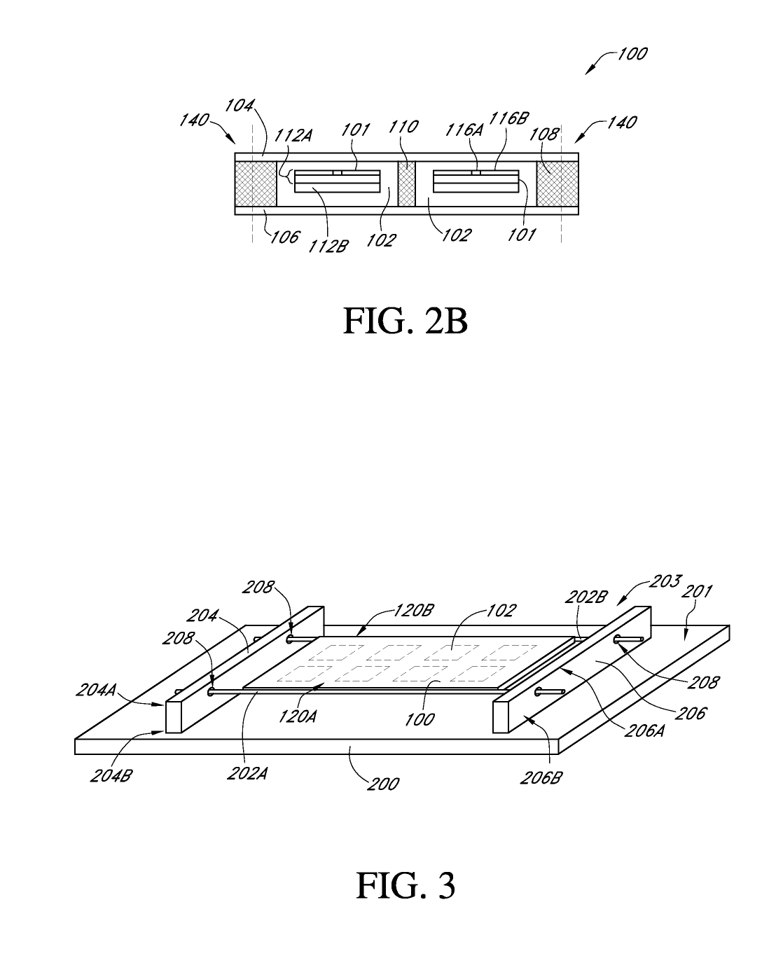

FIGS. 2A and 2B show a solar module in a top and a cross-sectional view, respectively. It is understood that the module 100 is exemplary and demonstrative and is drawn for the purpose of showing various aspects of the present inventions. The module 100 comprises a number of exemplary solar cells 101 which are electrically interconnected in series using conductive leads (not shown). It is possible that these solar cells may be shingled and, therefore, there may be no conductive leads interconnecting them. The electrically interconnected solar cells or so called solar cells strings are covered with a transparent and flexible encapsulant layer 102 which fills any hollow space among the cells and tightly seals them, preferably covering both of their surfaces. A variety of materials are used as encapsulants for packaging solar cell modules, such as ethylene vinyl acetate copolymer (EVA) and thermoplastic polyurethanes (TPU). However, in general, such encapsulant materials are moisture permeable; therefore, they must be further sealed from the environment by a protective shell 103, which forms a barrier to moisture transmission into the module package. The solar cells sealed within the protective shell 103 of the module 100 that may preferably include a top protective sheet 104 and a bottom protective sheet 106 and an edge sealant 108 extending between the top protective sheet and the bottom protective sheet. The edge sealant 108 is placed at the edge of the module structure and may be rectangular in shape in this example. For other module structures with different shapes, the edge sealant may also be shaped differently, following the circumference of the different shape modules. The protective shell 103 further comprises one or more divider sealants 110 that are formed within the protective shell, i.e. within the volume or space created by the top protective sheet 104, the bottom protective sheet 106 and the edge sealant 108. The divider sealant 110 may form a sealant pattern that divides the protective shell into sealed sections 111. Although there are two exemplary sealed sections 111 in the exemplary module 100 shown in FIG. 2A, there may be more sections. If moisture or other vapors enter into one of the sealed sections and damages a portion of a solar cell, other portions of the solar cell contained in other sections that are not affected by the moisture would continue producing power efficiently. This way, the overall performance of the module structure would be enhanced compared to a module without the sections. The edge sealant and divider sealants are materials that are highly resistive to moisture penetration. The water vapor transmission rate of the edge and divider sealants is preferably below 0.001 gm/m²/day, more preferably below 0.0001 gm/m²/day.

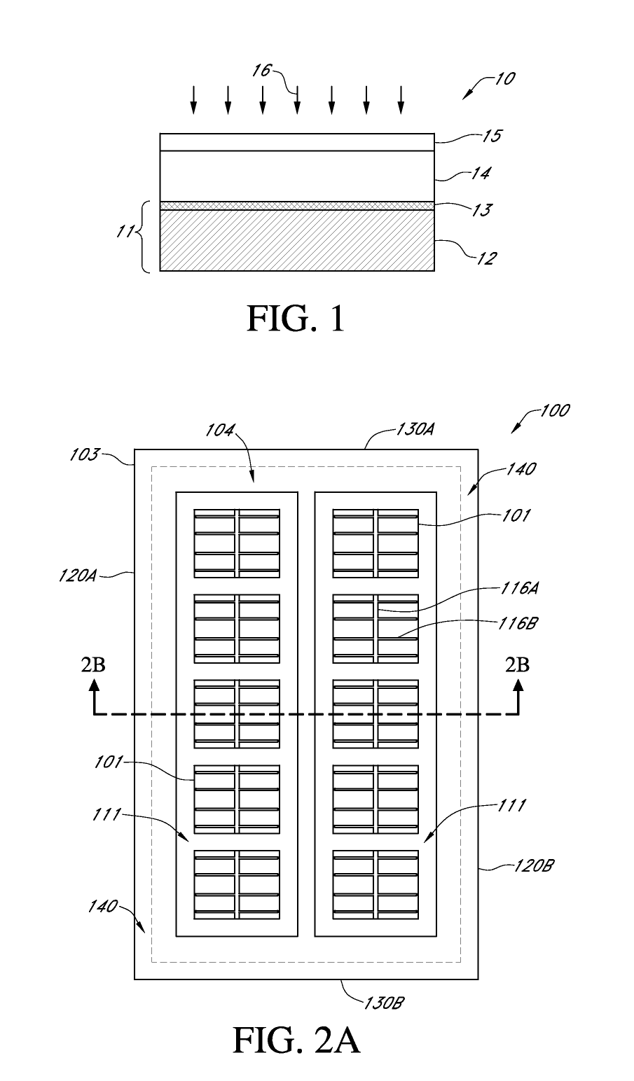

In the module 100, each solar cell 101 includes a front light receiving side 112A and a back side 112B. The solar cells 101 may be conventional CIGS based thin film solar cells, which are exemplified in FIG. 1. The front light receiving side 112A includes an absorber layer and a transparent layer deposited over the absorber layer. The absorber layer may be a Group IBIIIAVIA compound semiconductor layer such as a Cu (Ga, In) (Se, S)₂ thin film or CIGS. The transparent layer may include a stack including a buffer layer such as a CdS layer deposited over the absorber layer and a transparent conductive oxide (TCO) layer such as a ZnO layer deposited over the buffer layer. A conductive terminal structure 114 or conductive grid including busbars 116A and fingers 116B is disposed over the transparent oxide layer. The back side 112B of each solar cell 101 includes a substrate and a contact layer. The absorber layer of the front side 112A is disposed on the contact layer of the back side 112B. The contact layer may include Mo, Ta, Ti and W. The substrate may be a conductive substrate such as stainless steel or aluminum. In this embodiment, although the solar cells 101 are exemplified using CIGS based solar cells, they may be CIS, CdTe, amorphous silicon or silicon based solar cells, or the solar cells made of other materials.

A the front protective sheet 104 is typically a glass, but may also be a transparent flexible polymer film such as TEFZEL® from DuPont, polyethylene terephthalate (PET), polyethylene naphthalate (PEN)or another polymeric film with moisture barrier coatings. The back protective sheet 106 may be a sheet of glass or a polymeric sheet such as TEDLAR®, or another polymeric material which may or may not be transparent. TEDLAR® and TEFZEL® are brand names of fluoropolymer materials from DuPont. TEDLAR® is polyvinyl fluoride (PVF), and TEFZEL® is ethylene tetrafluoroethylene (ETFE) fluoropolymer. The back protective sheet 106 may comprise stacked sheets comprising polymer sheets with various sheet material combinations, such as metallic films, as a moisture barrier. The front and back support layer materials may preferably include EVA or thermoplastic polyurethane (TPU) material or both. The back protective polymeric sheet may also have a moisture barrier layer in its structure, such as a metallic film like an aluminum film. Light enters the module through the front protective sheet. The edge sealant or the divider sealant is a moisture barrier material that may be in the form of a viscous fluid which may be dispensed from a nozzle to the peripheral edge of the module structure and cured, or it may be in the form of a tape which may be applied to the peripheral edge of the module structure. There are a variety of such sealants available to solar module manufacturers. It is also possible that either one or both of the front protective layer and the back protective layer may be eliminated from the module structure.

As shown in FIG. 2A the exemplary module 100 includes a rectangular shape with two longitudinal edges, namely a first longitudinal edge 120A and a second longitudinal edge 120B, and two transversal edges, namely a first transversal edge 130A and second transversal edge 130B. An edge region 140 of the module may be used to attach the module to support structures used in this invention. The use of this peripheral region to secure the modules on support structures allows the modules to be easily installed and prevents any potential damage to the back and front protective sheets by eliminating any physical contact between such surfaces and the support structures or mechanisms. As will be described more fully below, the edge region 140 of the module 100 may be altered to attach the module to various support mechanisms or structures. Further, various auxiliary support members, such as sheets or rods, or other members made of metals or plastic may also be attached or adhered to the edge region to assist the installation of the modules.

FIG. 3 shows a method of installing the module 100 over a base 200, such as a flat base, including an upper surface 201, using a first edge support wire 202A attached to the first longitudinal edge 120A and a second edge support wire 202B attached to the second longitudinal edge 120B. The base 200 may be an outer surface of a structure, building or shelter such as facades, walls, rooftop, or an outer surface of a vehicle. The first and second edge support wires are in turn attached to a first support member 204 and the second support member 206. Accordingly, a support system 203 defined by the support members and edge support wires supports one or more solar modules 100 above the upper surface 201. If there are rooftop materials such as roof tiles, shingles or the like, on the upper surface 201, the support system 203 may hold the solar modules over such rooftop material, for example 1-30 cm above, preferably 5-10 cm above the rooftop material. The first support member 204 includes an upper end 204A and a lower end 204B, and similarly the second support member 206 includes an upper end 206A and a lower end 206B. The lower ends 204B and 206B of the first and second support members are held on the upper surface 201 of the base 200. The edge support wires 202A and 202B holding the solar module 100 are tensioned between the upper ends 204A and 206A of the first and the second support members 204 and 206 respectively. The edge support wires may be steel or aluminum alloy wires, aircraft cables or wire ropes. An exemplary edge support wire may be stainless steel or galvanized aircraft cable. A preferred diameter for the support wires may be in the range of 3/16-⅜ inches, more preferably about ¼ inches.

Through holes 208, the edge support wires 202A and 202B may be attached to the support members 204 and 206 by tying the ends of the edge support wires to the support members if the support members are permanently secured to the upper surface 201. In this configuration, the support members 204 and 206 carry the load of the solar module 100 and the edge support wires, and the support members are attached to preselected locations on the upper surface 201. For example, if the upper surface 201 is a rooftop, the preselected locations may preferably be the edges of the rooftop where the gutter is located so that installing the support members 204 and 206 will not damage the main roof structure as described above in the background section.

Alternatively, the edge support wires 202A and 202B may travel through the holes 208 of the support members 204 and 206, and are attached to other support members (not shown) which are in proximity to the first support member 204 and the second support member 206. In this case the, support members 204 and 206 may not be permanently secured to the upper surface 201; in fact, they are held in place by the tension applied by the first edge support wires and the second edge support wires passing through their upper ends. This flexibility in placement of support members allows the load carrying support members, i.e., where the edge support wires are tied to, to be located only at the preselected locations such as the edges of the rooftops so that no roof penetration is made to install the support members to the rooftop, which may damage the original roof structure. In the context of this invention, a roof penetration may be defined as any damage to the roof top; for example, drilling holes, or removing parts of the rooftop, or driving nails or screws or the like to it.

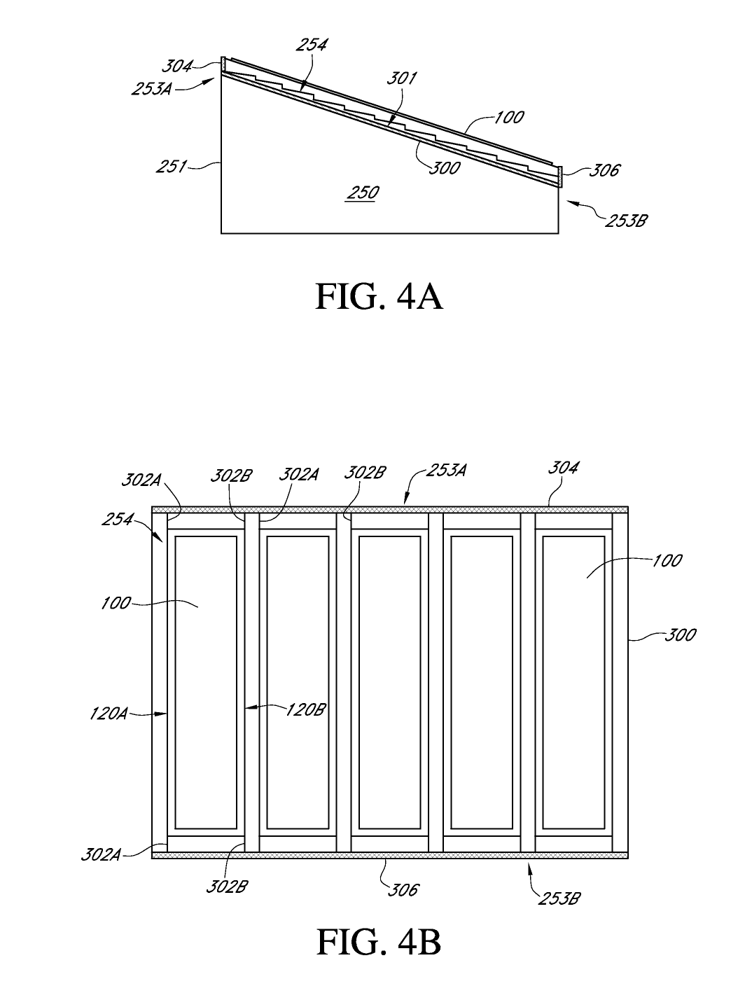

FIG. 4A exemplifies an embodiment of the present invention on a building 250 with a rooftop 300 having a rooftop surface 301 supported by building peripheral walls 251. In this example, the rooftop surface 301 is slanted between an upper roof edge 253A and a lower roof edge 253B and includes roofing material 254, such as tiles or shingles, disposed thereon. As shown in FIG. 4B in top view, a series of solar modules 100 are held between a first support member 304 secured to the upper roof edge 253A and a second support member 306 secured to the lower roof edge 253B, and above the rooftop surface 301. Each solar module 100 is suspended over the roofing material 254 by attaching a first edge support wire 302A to the first longitudinal edge 120A of the module and by attaching the second edge support wire 302B to the second longitudinal edge 120B of the module, thereby forming an array of suspended solar modules over the rooftop 300.

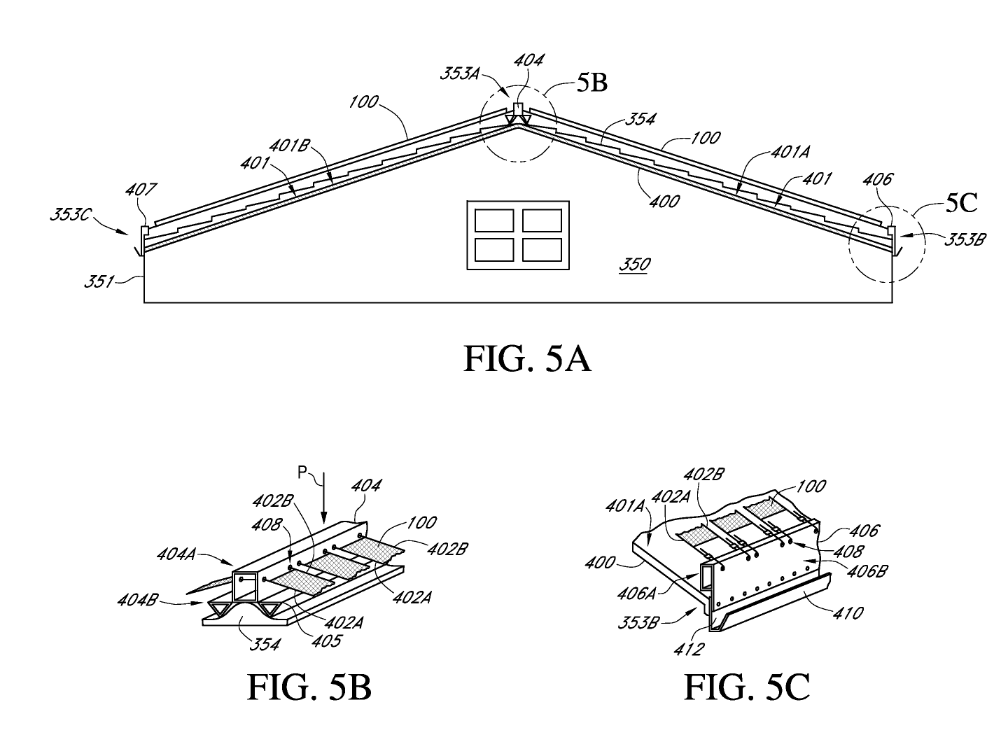

FIG. 5A exemplifies another embodiment of the present invention on a building 350 with a rooftop 400 having a rooftop surface 401 with a first rooftop surface section 401A and a second rooftop surface section 401B supported by building peripheral walls 351. In this example, both the first and second rooftop surface sections 301A and 301B are slanted. The first rooftop surface section 401A extends between an upper roof edge 353A and a first lower roof edge 353B and the second rooftop surface section 401A extends a between the upper roof edge 353A and a second lower roof edge 353C. Both rooftop sections 401A and 401B may include roofing material 354 such as roof tiles or shingles disposed thereon. A series of solar modules 100 may be held between a first support member 404 placed onto the upper roof edge 353A or top ridge and a second support member 406 secured to the first lower roof edge 353B, and another series of solar modules 100 may be held between the first support member 404 and a third support member 407 secured to the second lower roof edge 353C.

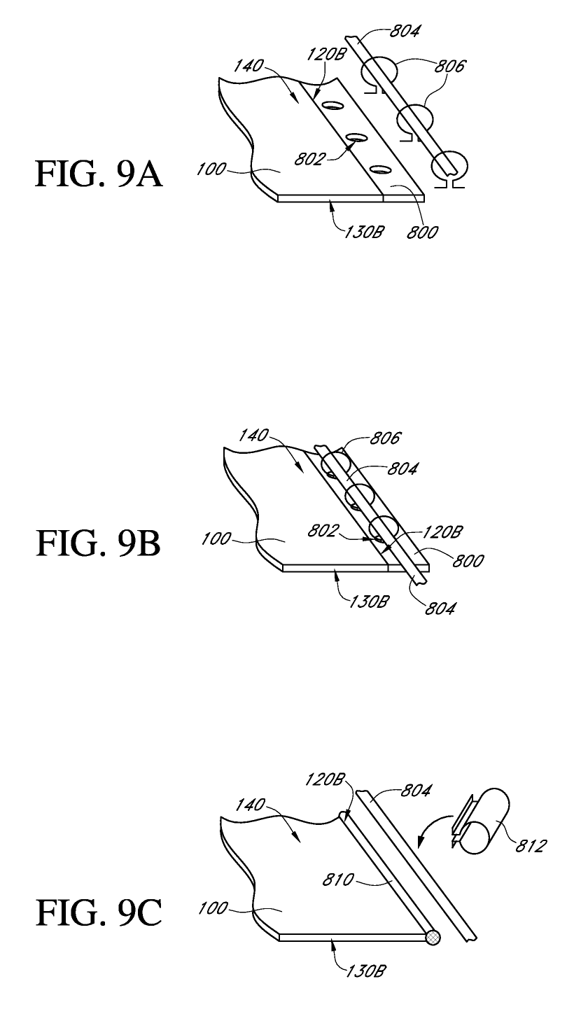

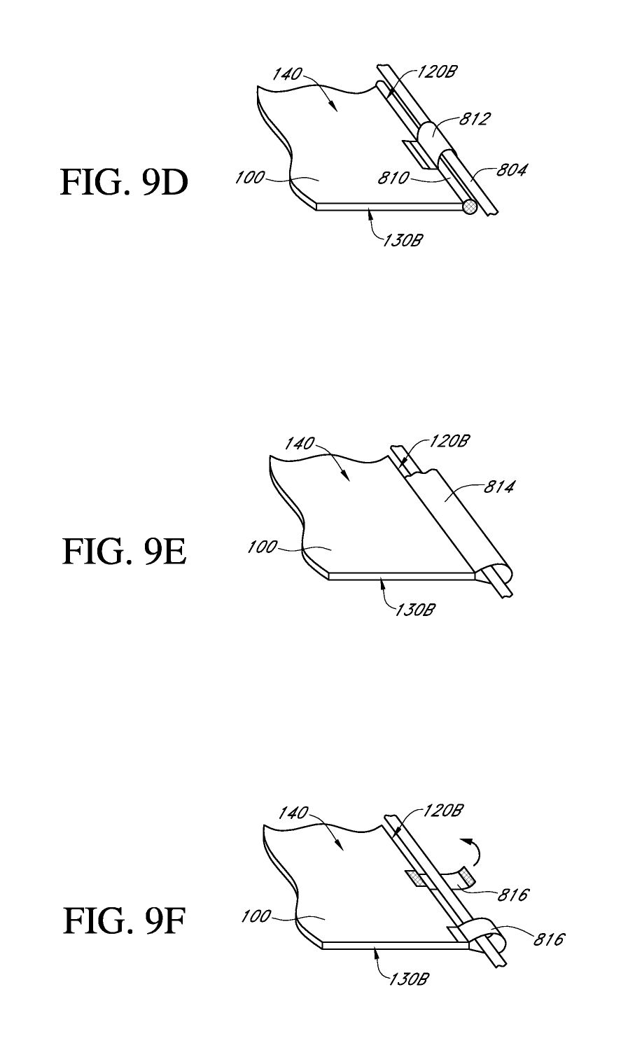

In this embodiment, both a first edge support wire 402A and a second edge support wire 402B extends from the second support member 406 to the third support member 407 through the first support member 404 as shown in FIGS. 5A, 5B and 5C, and thereby the first support member 404 is held in place on the upper roof edge 353A by the wire tension applied by the first and second edge support wires. In one embodiment, the first support member 404 is a floating stabilizer and it is not anchored to the rooftop. However, it may be attached to the top ridge 353A using a roofing adhesive. In another embodiment, a plurality of the first and second edge support wire pairs may be extended in a similar manner over the rooftop 400 establishing a wire frame to attach the solar modules. As shown in FIG. 5A, each pair of edge support wire supports two solar modules, i.e., one solar module over the first rooftop section 401A and another solar module over the second rooftop section 401B. Each solar module 100 is suspended over the roofing material 354 by attaching the first edge support wire 402A to the first longitudinal edge 120A of the module and by attaching the second edge support wire 402B to the second longitudinal edge 120B of the module, and thereby forming an array of suspended solar modules over the rooftop 400. In one embodiment, the edge support wires and the modules may be pre-assembled as preassembled sets by attaching one more modules to the pairs of edge support wires as described above before the installation, and during the installation, the preassembled sets are attached to the support members on the roof The edge support wires may be attached to the solar modules using the methods shown in FIGS. 9A-9F.

As shown in FIG. 5B in partial view and in FIG. 5A, the first support member 404 is placed onto the upper roof edge over the upper ends of the first and the second roof sections 401A and 401B. An upper end 404A of the first support member defines a tube that may include holes 408 for the edge support wires to pass through and press the first support member downwardly in the direction of arrow ‘P’, as described above. In one implementation, the tube is rectangular or square, for example a 2×2 inches tube, with holes on both sidewalls. Alternatively, the edge support wires may be tied to the first support member. A lower end 404B of the first support member 404 may include legs 405 to better stabilize the first support member on the rooftop. The first support member 404 may be made of aluminum or similar lightweight metal or alloys, and composite materials such fiberglass, or the like. In another embodiment, instead of the holes 408, the first support member 404 may have slits or channels, downwardly extending from the upper end 404A, to hold the edge support wires.

As shown in FIG. 5C in partial view and in FIG. 5A, the second and third support members, for example the second support member 406, includes an upper end 406A where the first and the second edge support wires 402A and 402B are attached and a lower end 406B that is secured to the first lower roof edge 353B. The upper end 406A may include a rectangular or square tube, for example a 1×1 inch tube, including holes 408 in predetermined locations. As shown in FIG. 5C, the edge support wires may be tied to the upper end 406 A by passing the wires through the holes 408 and looping around the upper end. The edge support wires may include a tensioning tool or device such as a turnbuckle to tension the wires after attaching them to the support members. Depending on the desired edge support wire configuration, wires are tensioned after attached to the support members. The edge support wires may be attached to the support member using many conventional techniques. Alternatively, the edge support wires may be advantageously attached to the support members using the tensioning device by fastening its one end to the support member and the other end to the edge support wire. The lower end 406B may be a rectangular plate attached to the upper end 406A. The lower end 406B of the second support member 406 may be attached to a roof support stud (not shown). In another embodiment, the lower end 406B may be placed within a rain gutter 410 and bolted to the roof support stud through a rain gutter support plate 412. Alternatively, the rain gutter support plate 412 may form the lower end of the second support member 406 and the upper end 406A, which may be shaped as a tube, may be attached to the rain gutter support plate 412 by bolting or welding.

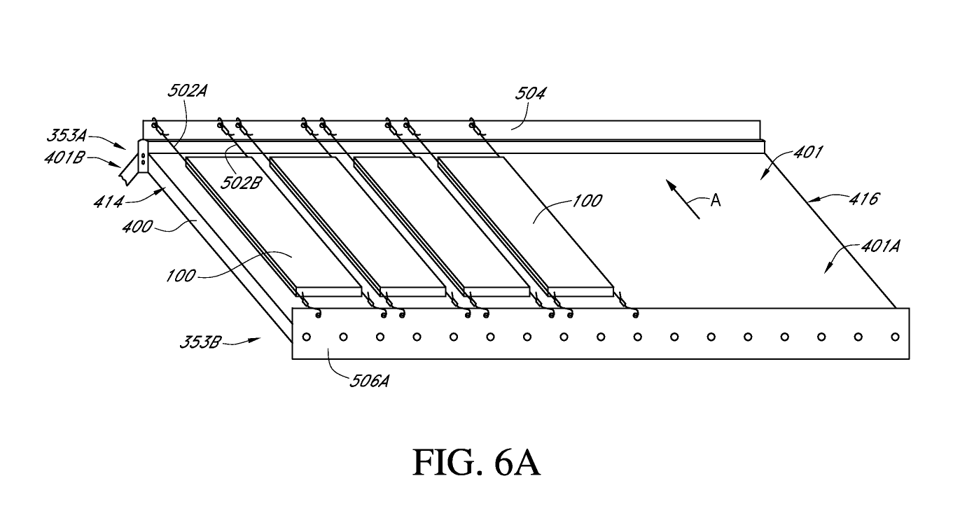

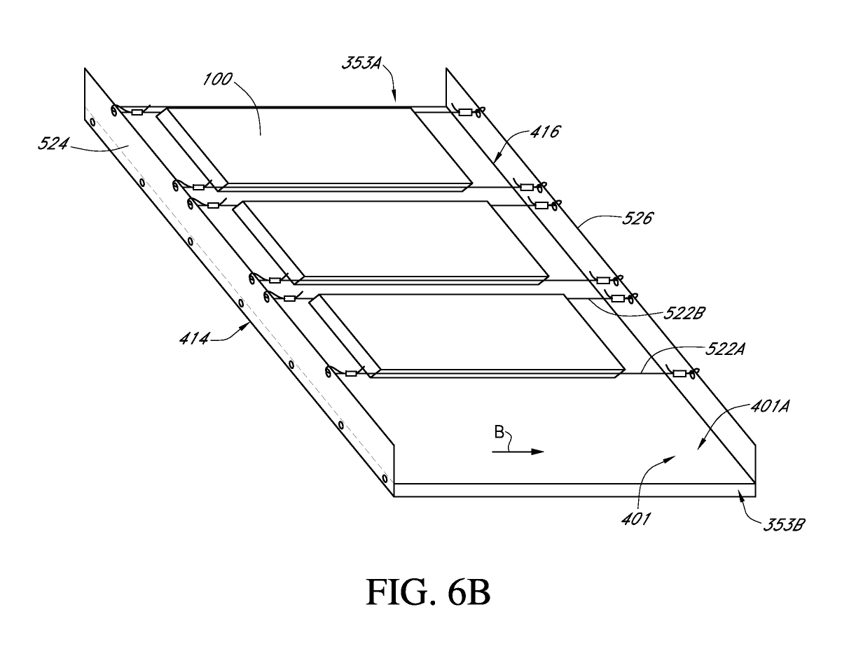

In an alternative embodiment shown in FIG. 6A, ends of a first support member 504 may be attached to a front roof edge 414 and a back roof edge 416 of the building 350 by bolting. A series of solar modules 100 may be held over the first rooftop surface portion 401A, between the first support member 504 which is secured to the upper roof edge 353A and a second support member 506A which is secured to the first lower roof edge 353B. Further, as described above, another series of solar modules 100 may be held over a second rooftop surface portion 401B and between the first support member 504 and a third support member (not shown) secured to the second lower roof edge 353C (shown in FIG. 5A). In this embodiment, both a first edge support wire 502A and a second edge support wire 502B extends from the first support member 504 to the second support member 506A. It will be appreciated that the same installation principles may be applied to install solar modules in various directions above the rooftop. In FIG. 6A, as well as in FIGS. 4A-5C, the solar modules are installed along a first direction depicted by arrow ‘A’ which is parallel to the rooftop surface 401 and the front and back roof edges 414 and 416 so that the solar modules 100 extend between the upper roof edge and the lower roof edges as shown in the figures. In this configuration, the longitudinal edges of the modules are parallel to the arrow ‘A’ which is parallel to the rooftop surface portion 401A, and is generally perpendicular to the upper roof edge 353A and the first lower roof edge 353B. The first, second and third support members may be made of steel or aluminum.

Alternatively, as shown in FIG. 6B, the solar modules may also be installed in a direction depicted by arrow ‘B’ which is parallel to the rooftop surface portion 401A and the upper roof edge 353A and the first lower roof edge 353B so that the solar modules 100 extend between the edges of the rooftop. In this configuration, the longitudinal edges of the modules are parallel to the arrow ‘B’. In this embodiment, a front edge support member 524 may be attached to the front roof edge 414 and a back edge support member may be attached to the back roof edge 416 of the building 350. The solar modules 100 are held over the first rooftop surface portion 401A and between the front edge support member 524 and the edge support member 526 by a first edge support wire 522A and a second edge support wire 522B, and another series of solar modules 100 may be held over a second rooftop surface portion 401B (FIG. 5A) in the same manner.

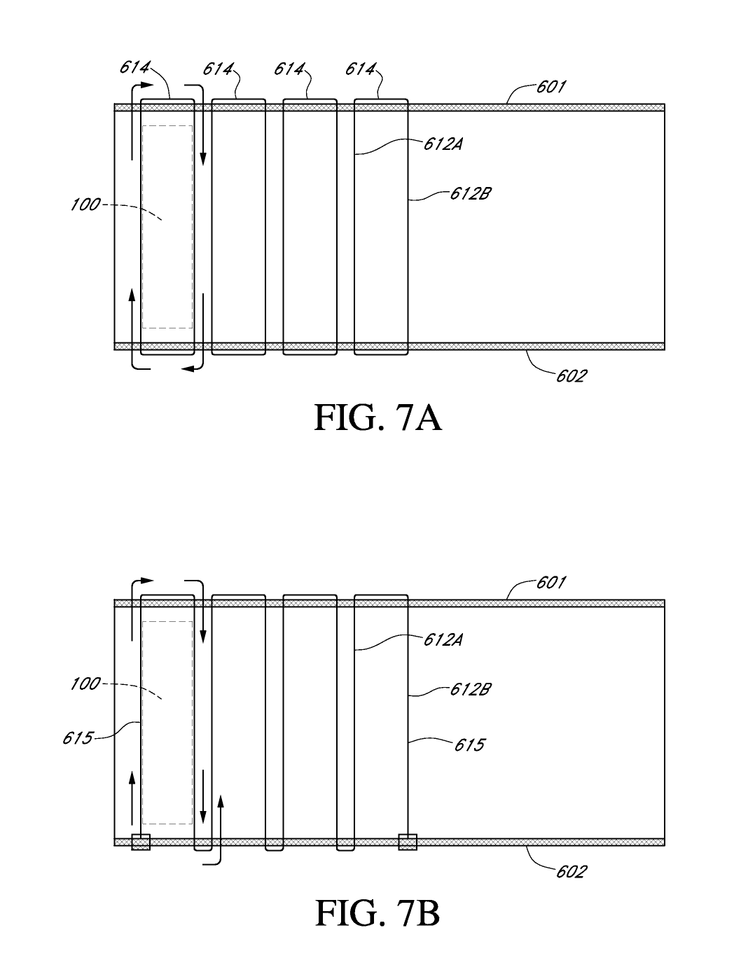

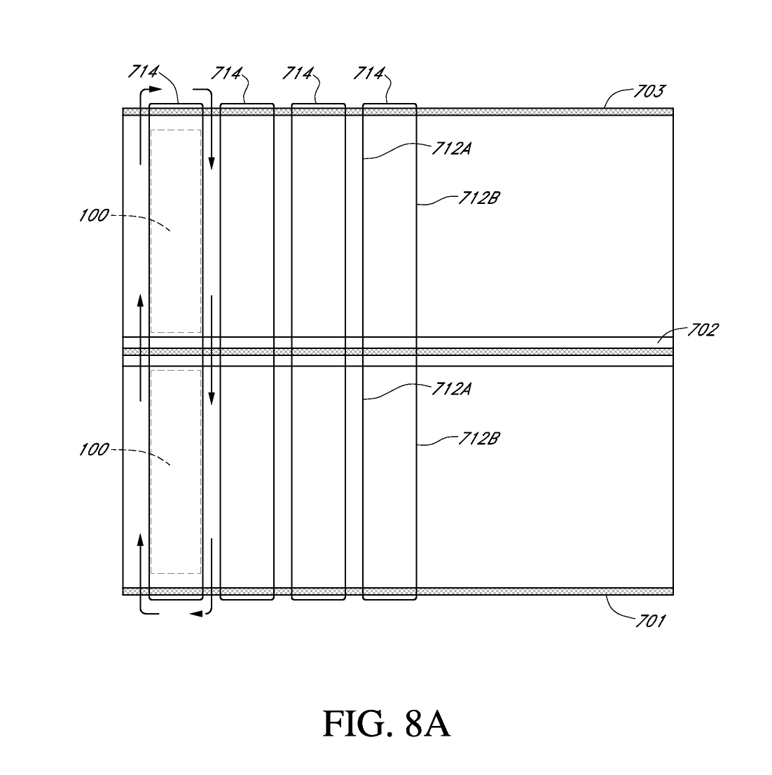

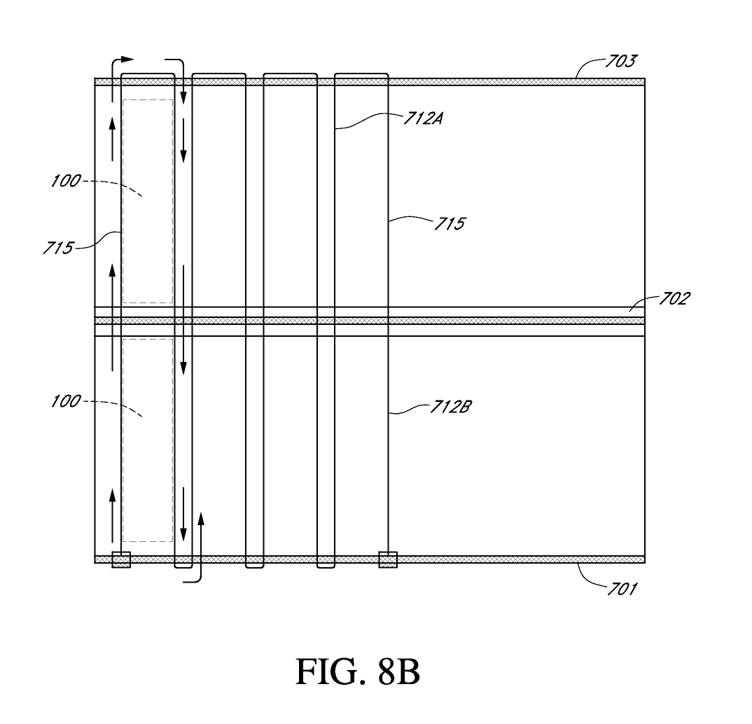

In addition to the embodiments shown above, FIGS. 7A-8B show various alternative embodiments to form edge support wire networks tensioned between the support members. As shown in FIG. 7A, between a first support member 601 and a second support member 602, pairs of first edge support wires 612A and second edge support wires 612B may be formed by looping wire pieces 614 between the first and second support members in the direction of the arrows. As shown in FIG. 7B, the pairs of the first edge support wires 612A and the second edge support wires 612B may be formed by running a single wire 615 between the first and second support members 601 and 602 in the direction of the arrows. In this configuration, the ends of the wire 615 are secured to either or both support members. These wiring networks may replace wiring methods used with the embodiments described in connection with FIGS. 4A-4B and 6A-6B.

The wiring networks shown in FIGS. 8A and 8B may replace wiring methods used with the embodiments described in connection with FIGS. 5A-5C. As shown in FIG. 8A, between a first support member 701 and a third support member 703 and through a second support member 702, pairs of first edge support wires 712A and second edge support wires 712B may be formed by looping wire pieces 714 between the first and third support members in the direction of the arrows. As shown in FIG. 8B, the pairs of the first edge support wires 712A and the second edge support wires 712B may be formed by running a single wire 715 between the first support member 701 and the third support member 703 and through the second support member 702 in the direction of the arrows. In this configuration the ends of the wire 715 are secured to either or both support members 701 and 703, for example, using conventional fastening means.

The solar modules 100 may be attached to the edge support wires by the longitudinal edges 120A and 120B shown in FIG. 2A using various techniques including, but not limited to, the techniques shown in the following FIGS. 9A-9F.

FIG. 9A shows a corner section of the solar module 100 shown in FIGS. 2A-2B. The edge region 140 adjacent the longitudinal edges 120A and 120B may be modified to include an edge strip 800 having holes 802. The strip 800 which may be a polymeric or metallic material may be glued to the solar module 100. An edge support wire 804 may be attached to the solar module 100 using clips 806 as shown in FIGS. 9A-9B.

In another technique, as shown in FIG. 9C, an edge rod 810 may be glued to the edge region 140. As shown in FIG. 9D, a spring clip 812 is used to hold the edge support wire 804 and the edge rod 810 together. The edge rod 810 prevents the spring clip 812 from slipping off the edge region of the solar module.

As shown in FIG. 9E, a flexible tube 814 may be attached to the edge region 140 to hold the edge support wire 804. As shown in FIG. 9F, hook and loop (Velcro®) straps 816 may be used to hold the edge support wire 804. The techniques shown in FIGS. 9A-9F may be used to attach the solar modules to the edge support wires installed on the rooftop as described above. Alternatively, these techniques may be used to preassemble edge wires and the modules as preassembled sets before the rooftop installation. The preassembled sets are subsequently installed on the rooftops with the support members.

The present invention replaces prior art solar module installation methods that anchor solar panels to the rooftops by penetrating into the roofing materials and seals. The solar modules are attached to wire systems and can be easily positioned by moving them up and down or right to left. The solar modules can be attached to wires using different methods allowing easy maintenance or replacement while keeping the rest of the solar modules in place.

Although aspects and advantages of the present inventions are described herein with respect to certain preferred embodiments, modifications of the preferred embodiments will be apparent to those skilled in the art.

It will be appreciated that various substitutions, modifications and changes to the form and the detail of the apparatus and methods of the invention may be made by those skilled in the art without departing from the spirit and scope of the present invention. Hence, the present invention should not be limited or defined by the aforementioned description, but should be defined by the appended claims.

What is claimed is:

1. A solar shell for a rooftop on a building having sidewalls, the solar shell including flexible solar cell modules, comprising:
at least one support structure formed on a rooftop including a roofing material, the at least one support structure including:
a first support member having a lower end and an upper end, wherein the upper end of the first support member is attached to a first location on the building;
a second support member having a lower end and an upper end, wherein the lower end of the second support member is attached to a second location on the building;
a first edge support wire segment extending between the upper ends of the first and second support members; and
a second edge support wire segment, which is substantially parallel to the first wire, tensioned between the upper ends of the first and second support members; and
a flexible sheet-shaped solar module, including a plurality of solar cells, movably attached to the first and second edge support wire segments by fastening a first longitudinal peripheral edge of the flexible sheet-shaped solar module to the first wire segment and by fastening a second longitudinal peripheral edge of the flexible sheet-shaped solar module to the second wire segment and thereby orienting the flexible sheet-shaped solar module generally parallel to the rooftop.

2. The solar shell of claim 1, wherein the first and the second support members are configured so that the first and second support members are connected to the sidewalls of the building so as to extend upward above the rooftop so that the interconnection between the first and second support members and the building does not result in penetrations being made in the rooftop to secure the first and second support members to the building.

3. The solar shell of claim 1, wherein the rooftop has a first and a second angled section that interconnect at a peak and the solar shell further comprises a third support member that is contoured to be positioned on the peak and wherein the third support member receives the first and second edge support wire segments and the tension in the first and second edge support wire segments urges the third support member downward to maintain the third support member on the peak.

4. The solar shell of claim 3, wherein the third support member is further secured to the peak through adhesive applied to the interface between the third support member and the peak of the roof.

5. The solar shell of claim 4, wherein the third support member includes an upper end that defines a tube that includes holes that permit the edge support wire segments to extend therethrough.

6. The solar shell of claim 5, wherein the third support member further comprises a first and a second leg attached to the tube wherein the first and second legs are adapted to engage with the first and second angled sections of the rooftop on either side of the peak to facilitate retention of the third support member on the peak.

7. The solar shell of claim 1, wherein the first and second edge support wire segments are formed out of two segments of a single edge support wire wherein a first segment extends between the first and second support members and the second segment is returned from the second support member to the first support member.

8. The solar shell of claim 1, wherein the peripheral edge regions of the flexible sheet-shaped solar module include holes that are used to interconnect with the first and second edge support wire segments via clips.

9. The solar shell of claim 1, further comprising an edge rod that is glued to the peripheral edge regions of the flexible sheet-shaped solar module and spring clips that are used to interconnect the edge rod to the first and second edge support wire segments.

10. The solar shell of claim 1, further comprising flexible tubes that are coupled to the peripheral edge regions so that the first and second edge support wire segments can be inserted into the flexible tubes to secure the flexible sheet-shaped solar module.

11. The solar shell of claim 1, further comprising pieces of hook and loop fastener that are attached to the peripheral edges and couple the flexible sheet-shaped solar module to the first and second edge support wire segments.

12. A solar cell assembly for mounting on the rooftop of a building having horizontal surfaces adjacent the sidewall, the assembly comprising:
a plurality of support members attached to the building wherein the plurality of support members includes at least one floating support member;
a plurality of wire segments that extend between the plurality of support members under tension wherein the plurality of wire segments are arranged into pairs of wire segments and wherein the plurality of wire segments exert a downward force on the at least one floating support member to retain the at least one floating support member in contact with the rooftop; and
a plurality of flexible solar panel sheets having solar cells formed thereon, wherein the plurality of flexible solar panel sheets are coupled between pairs of wire segments so that the tension on the wire segments suspend the plurality of flexible sheets over the rooftop.

13. The solar cell assembly of claim 12, wherein the plurality of support members include a first and a second support members that are configured so that the first and second support members are connected to the sidewalls of the building so as to extend upward above the rooftop so that the interconnection between the first and second support members and the building does not result in holes being formed in the rooftop to secure the plurality of support members to the building.

14. The solar cell assembly of claim 13, wherein the first and second support members are adapted to be connected to gutters attached to the sidewall of the building.

15. The solar cell of claim 12, wherein the rooftop has a first and a second angled section that interconnect at a peak and the at least one floating support member is contoured to be positioned on the peak.

16. The solar cell assembly of claim 15, wherein the at least one floating support member is further secured to the peak through adhesive applied to the interface between the at least one support member and the peak of the roof.

17. The solar cell assembly of claim 15, wherein the at least one floating support member includes an upper end that defines a tube that includes holes that permit the wire segments to extend therethrough.

18. The solar cell assembly of claim 17, wherein the at least one floating support member further comprises a first and a second leg attached to the tube wherein the first and second legs are adapted to engage with the first and second angled sections on either side of the peak to facilitate retention of the floating support member on the peak.

19. The solar shell of claim 12, wherein the plurality of wires define a first and a second edge support wire segments that are formed out of two segments of a continuous wire wherein a first segment extends between a first and a second support members and the second segment is returned from the second support member to the first support member.

20. The solar cell assembly of claim 19, wherein the plurality of flexible sheets include a plurality of sheets that are positioned adjacent each other so as to be substantially parallel between the first and second support members.

21. The solar cell assembly of claim 20, wherein the plurality of wire segments are comprised of a plurality of support wire segments of a single support wire that extends between the plurality of support members along each peripheral side of the plurality of flexible members.

22. The solar cell assembly of claim 12, wherein the peripheral edges of the flexible sheet include holes that are used to interconnect with the plurality of wire segments via clips.

23. The solar cell assembly of claim 12, further comprising an edge rod that is glued to the peripheral edge regions and spring clips that are used to interconnect the edge rod to the plurality of wire segments.

24. The solar cell assembly of claim 12, further comprising flexible tubes that are coupled to the peripheral edge regions so that the plurality of wire segments can be inserted into the flexible tubes to secure the flexible sheet.

25. The solar cell assembly of claim 12, further comprising pieces of hook and loop fastener that are attached to the peripheral edges and couple the flexible sheet to the plurality of wire segments.

26. A method of installing flexible solar panels on the rooftop of a building, the method comprising:
installing a plurality of support members to the portions of the building so that the support members extend above the rooftop;
extending a plurality of wire segments between the plurality of support members so that the one or more wires extend over the rooftop; and
mounting flexible solar panel sheets including solar cells to the plurality of wires so that the flexible sheets are positioned over the rooftop.

27. The method of claim 26, wherein installing the plurality of support members comprises mounting at least one of the plurality of support members to a gutter attached to the building.

28. The method of claim 26, wherein installing the plurality of support members comprises mounting at least one of the plurality of support members to a sidewall adjacent the rooftop.

29. The method of claim 26, wherein installing the plurality of support members includes positioning a floating support member on the roof wherein the wires engage with the floating support member and the tension on the wire urges the support member towards the rooftop.

30. The method of claim 29, wherein the floating support member is attached to the rooftop via an adhesive.

31. The method of claim 26, wherein extending the plurality of wires between the plurality of support members comprises using a single wire to extend between the plurality of support members wherein the single wire defines the plurality of wire segments.

32. A method of installing flexible solar panels including solar cells on rooftop of a building, the method comprising:
installing a plurality of support members to the portions of the building so that the support members extend above the rooftop; and
extending a plurality of flexible solar panels between the plurality of support members by attaching one or more edge support wires of each flexible solar panel to the plurality of support members so that the flexible solar panels are positioned over the rooftop.

33. The method of claim 32 further comprising the step of attaching the edge support wires to the flexible solar panels before the step of extending.

34. The method of claim 33, wherein installing the plurality of support members comprises mounting at least one of the plurality of support members to a sidewall adjacent the rooftop.

35. The method of claim 34, wherein installing the plurality of support members includes positioning a floating support member on the roof wherein the edge support wires engage with the floating support member and the tension on the edge support wire urges the support member towards the rooftop.

36. The method of claim 35, wherein the floating support member is attached to the rooftop via an adhesive.
